(19) United States
(12) Patent Application Publication
(10) Pub. No.: US 2015/0295559 A1
(43) Pub. Date: Oct. 15, 2015

(54) MULTIPLEXER USING MULTIPLE TUNED OUTPUT IMPEDANCES FOR REDUCED HARMONIC GENERATION

(71) Applicant: Avago Technologies General IP (Singapore) Pte. Ltd., Singapore (SG)

(72) Inventors: Christopher White, Portola Valley, CA (US); Herbert L. Ko, San Jose, CA (US)

(73) Assignee: Avago Technologies General IP (Singapore) Pte. Ltd., Singapore (SG)

(21) Appl. No.: 14/248,865

(22) Filed: Apr. 9, 2014

(51) Int. Cl. H03H 9/70; H04B 1/48; H04B 1/04; H03H 9/54

(52) U.S. Cl. CPC H03H 9/706; H03H 9/547; H04B 1/48; H04B 1/0475; H04B 2001/485; H04B 2001/0408

(57) ABSTRACT

A multiplexer comprises a plurality of filters connected to a common node and each comprising a plurality of acoustic resonators, and a plurality of harmonic traps each integrated into a corresponding one of the plurality of filters and configured to suppress harmonic generation of another one of the filters.

### BACKGROUND

Mobile phones and other wireless devices may generate spurious emissions due to nonlinear response characteristics of their component parts. For example, FIG. 1 shows certain components of a communication device 100 which may generate spurious emissions during signal transmission. The components shown in FIG. 1 may form a front end of a mobile phone, for instance.

Referring to FIG. 1, communication device 100 comprises a power amplifier (PA) 105, a radio frequency (RF) switch 110, filters 115, and an antenna switch 120. During signal transmission, signals received at a PA port are amplified by PA 105, transmitted through RF switch 110 to a designated one of filters 115, and then transmitted through antenna switch 120 to an antenna port. Although not shown in FIG. 1, signals received at the PA port may be transferred though additional filters and/or antenna ports. Additionally, filters 115 may be replaced by duplexers or multiplexers to allow additional forms of communication.

Filters 115 (or alternatively, duplexers or multiplexers) may be implemented by acoustic resonators, such as Surface Acoustic Wave (SAW) resonators, Bulk Acoustic Wave (BAW) resonators, Film Bulk Acoustic Wave Resonators (FBARs). These acoustic resonators typically generate spurious output signals at second or third harmonics of a transmit carrier frequency due to nonlinearity of a piezoelectric material contained therein. In general, it is desirable to reduce these and other spurious emissions to improve the quality of communication and to avoid interfering with other communications.

One conventional method for canceling the second harmonic power (H2) generated by an acoustic resonator device is to cross connect two parallel, equal area resonators, called a splitbar. Another conventional method, called a powerbar, uses two equal area resonators in series, where each resonator has twice the area of the original device, and the resonators are connected to with opposing piezoelectric orientations. The powerbar method is effective but increases the total area of the filter, increasing the cost.

In view of the above shortcomings of conventional technologies, there is a general need for improved filter and multiplexer circuits in which H2 generation is reduced without an increase in the area of acoustic resonator devices in each filter or the size of a multiplexer module.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a block diagram illustrating an RF front end from power amplifier to antenna for a mobile phone or other wireless device.

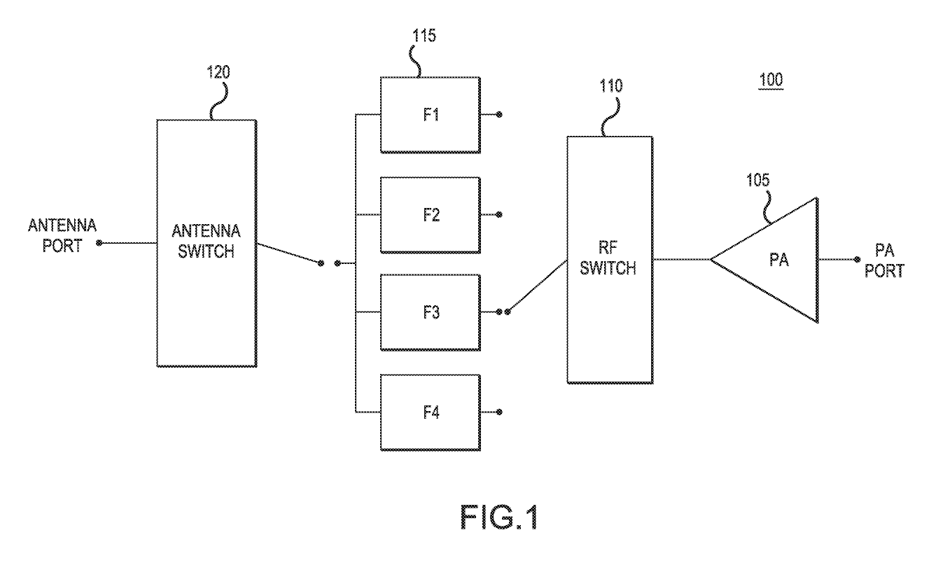

FIG. 2 is a circuit diagram of a device comprising a ladder filter and an external harmonic trap, according to a representative embodiment.

FIG. 3A is a block diagram of a duplexer using a harmonic trap for suppression of transmit (TX) filter harmonic output, according to a representative embodiment.

FIG. 3B is a circuit diagram of a receive (RX) filter comprising a single harmonic trap for suppression of 2^{nd} harmonic generation, according to a representative embodiment.

FIG. 3C is a perspective view of an FBAR duplexer module comprising tuned inductors implemented by traces in a multilayer printed circuit board (PCB) substrate, according to a representative embodiment.

FIG. 3D is a side view of the FBAR duplexer module of FIG. 3C, according to a representative embodiment.

FIG. 4A is a simplified equivalent circuit illustrating an antenna side impedance of a single FBAR filter with circuit elements of a harmonic trap, according to a representative embodiment.

FIG. 4B is a simplified equivalent circuit for the harmonic trap of FIG. 4A at a series resonance frequency fᵣₑₛ, according to a representative embodiment.

FIG. 5 is a circuit diagram illustrating a diplexer comprising double integrated harmonic traps for suppression of 2^{nd} harmonic generation, according to a representative embodiment.

FIG. 6 is a circuit diagram illustrating a multiplexer comprising multiple integrated harmonic traps for suppression of 2^{nd} harmonic generation, according to a representative embodiment.

FIG. 7 is a graph illustrating diplexer antenna side output impedance, including low impedance resulting from a double harmonic trap, according to a representative embodiment.

FIG. 8 is a graph illustrating simulated 2^{nd} harmonic power output from a diplexer with and without an integrated double harmonic trap, according to a representative embodiment.

### DETAILED DESCRIPTION

In the following detailed description, for purposes of explanation and not limitation, example embodiments disclosing specific details are set forth in order to provide a thorough understanding of the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

The terms ‘a’, ‘an’ and ‘the’ include both singular and plural referents, unless the context clearly dictates otherwise. Thus, for example, ‘a device’ includes one device and plural devices. The terms ‘substantial’ or ‘substantially’ mean to within acceptable limits or degree. The term ‘approximately’ means to within an acceptable limit or amount to one of ordinary skill in the art. Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element. Other relative terms may also be used to indicate the relative location of certain features along a path such as a signal path. For instance, a second feature may be deemed to “follow” a first feature along a signal path if a signal transmitted along the path reaches the second feature before the second feature.

The described embodiments relate generally to multiplexers comprising acoustic resonator based filters in which second or higher order harmonic generation is suppressed at an antenna port (or some other common node) by tuning an output impedance of each filter to a series resonance at or near to a second harmonic frequency of one or more other filters. For example, in certain embodiments a diplexer (i.e., a 1:2 multiplexer) comprises a first filter and a second filter, wherein an impedance of the first filter is tuned to resonate at a second harmonic frequency of the second filter, and an impedance of the second filter is tuned to resonate at a second harmonic frequency of the first filter. A series resonant or harmonic trap for each filter circuit can be implemented using an antenna side series input inductance (LTx), a capacitance of a first series FBAR resonator on the antenna side (Cs1), a capacitance of a first shunt FBAR resonator on the antenna side (Ch1), and PCB inductance from a first shunt FBAR on the antenna side to a module ground (L1). The series combination of LTX, Cs1, Ch1, and L1 forms a series resonant circuit. The PCB inductance to ground L1 can be adjusted during a design process to achieve a desired resonant frequency at the second harmonic of an opposing filter.

The combination of multiple tuned output impedances can potentially reduce H2 emissions to power levels lower than for a single harmonic trap, and without increasing the size, cost, or adding external components to the multiplexer module.

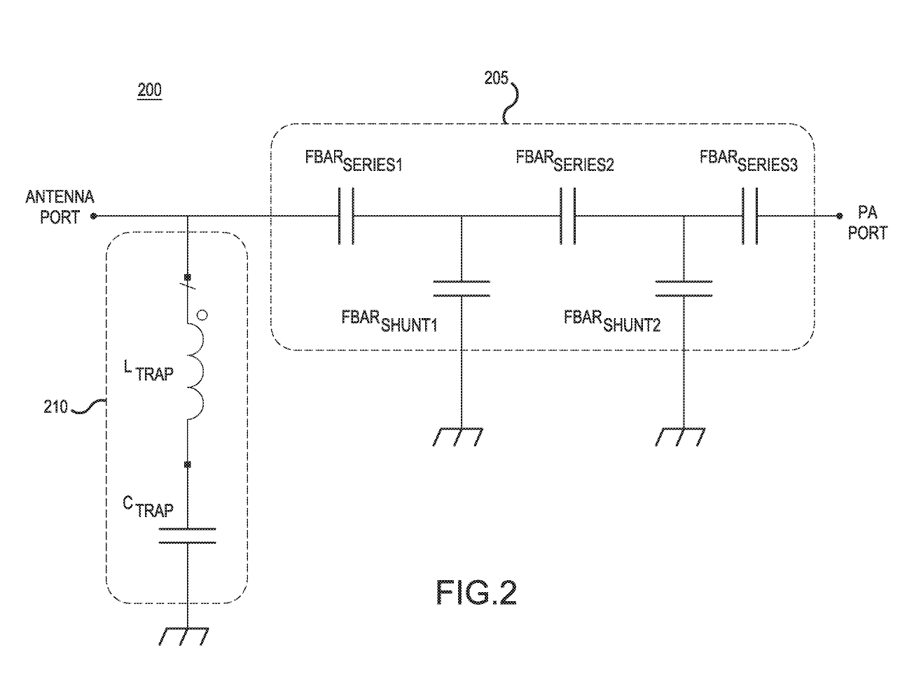

FIG. 2 is a circuit diagram of a device 200 comprising a ladder filter 205 and an external harmonic trap 210, according to a representative embodiment.

Referring to FIG. 2, ladder filter 205 comprises three series FBARs, labeled FBARₛₑᵣᵢₑₛ₁, FBARₛₑᵣᵢₑₛ₂, and FBARₛₑᵣᵢₑₛ₃, and two shunt FBARs, labeled FBARₛₕᵤₙₜ₁ and FBARₛₕᵤₙₜ₂. Alternatively, it could include more FBARs, e.g., 4 series FBARs and 3 shunt FBARs. The illustrated FBARs are arranged between a PA port and an antenna port as shown in the diagram. Harmonic trap 210 comprises a series resonance connected in parallel at an output of the ladder filter. The series resonance comprises a trap inductance Lₜᵣₐₚ and a trap capacitance Cₜᵣₐₚ arranged in series between the antenna port and ground.

The harmonic trap circuit may be tuned to a series resonance (low impedance) at the second harmonic of a filter operating band, for example. The trap may present a low impedance at the second harmonic, which results in a mismatch to the load of the filter, and therefore reduced harmonic power at the antenna or load.

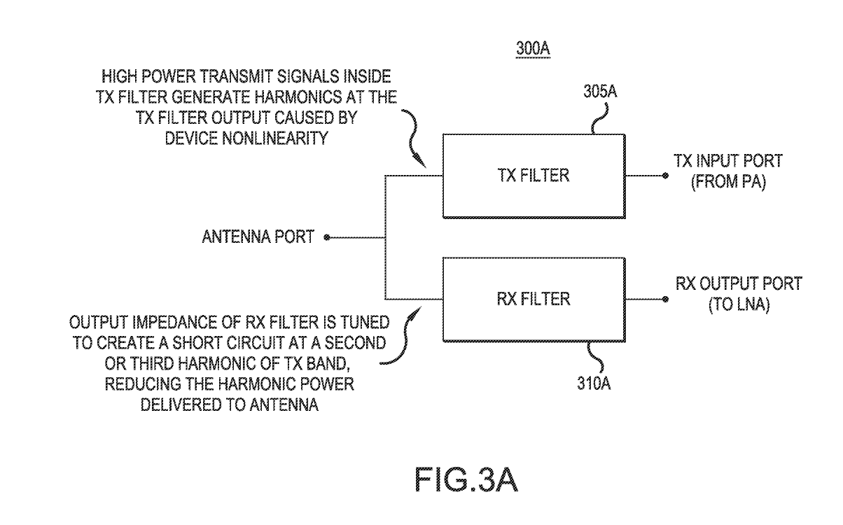

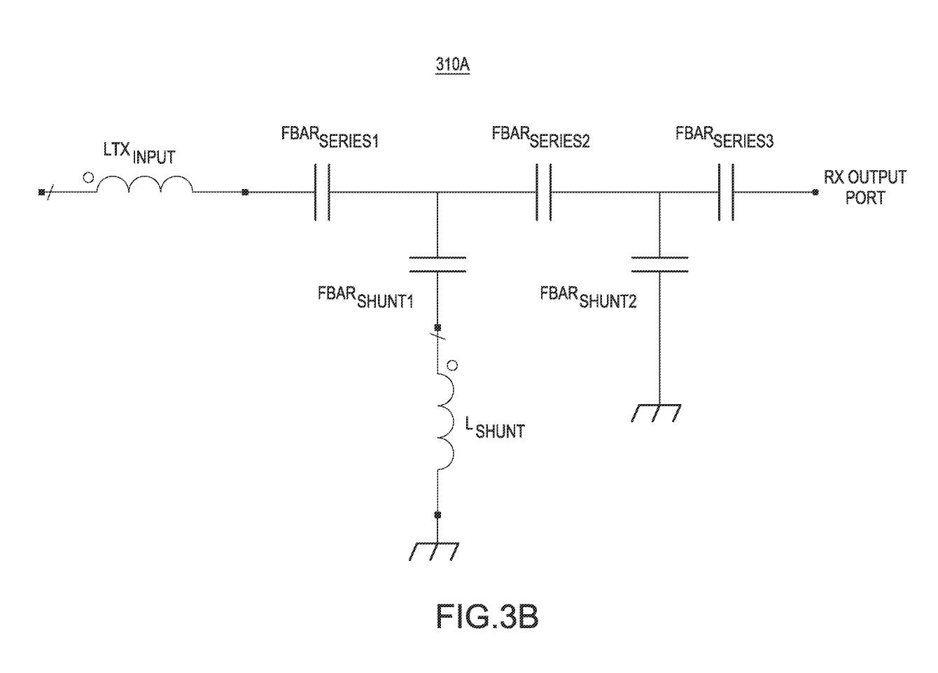

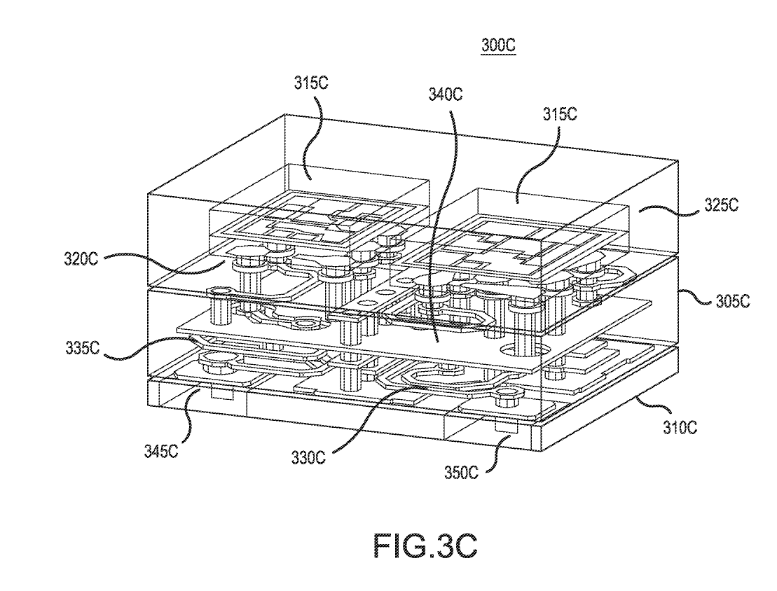

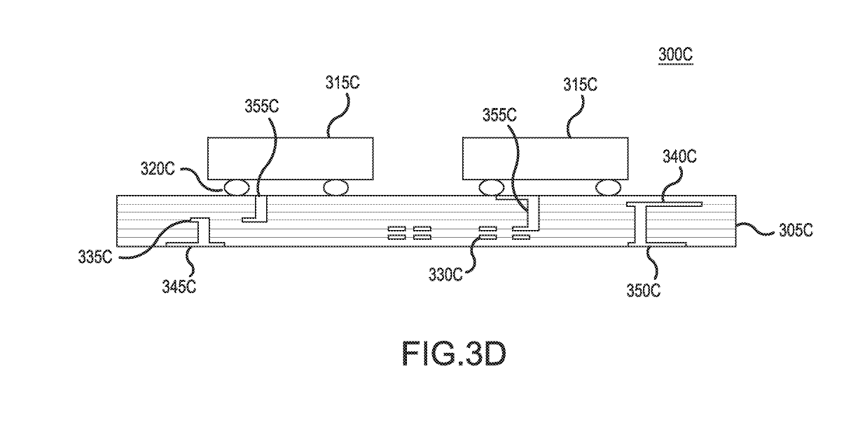

Ladder filter 205 is typically implemented in a module that is mounted on a printed circuit board (PCB), and the external harmonic trap is typically implemented by surface mount components placed on the PCB or integrated into layers of the PCB. Examples of such implementations are illustrated in FIGS. 3C and 3D.

FIG. 3A is a block diagram of a duplexer 300A using a harmonic trap for suppression of TX filter harmonic output, according to a representative embodiment.

Referring to FIG. 3A, duplexer 300A comprises a TX filter 305A and an RX filter 310A connected to an antenna port. TX filter 305A receives relatively high power signals from a power amplifier, filters the received signals according to a TX band, and transmits the filtered signals to the antenna port. RX filter 310A receives relatively low power signals from the antenna port, filters the received signals according to an RX band, and transmits the filtered signals to a low noise amplifier (LNA). Each of the TX filter and the RX filter may be implemented by a ladder filter as illustrated by FIG. 2, for example.

The high power signals from TX filter 305A generate harmonics at a TX filter output due to nonlinearity of devices in TX filter 305A, including acoustic resonators. To suppress the harmonics generated by TX filter 305A, an output impedance of RX filter 310A is tuned to create a short circuit at the second (or third) harmonic of the TX band. This, in turn, reduces the harmonic power delivered to the antenna port.

FIG. 3B is a circuit diagram of RX filter 310A comprising a single harmonic trap for suppression of 2^{nd} harmonic generation, according to a representative embodiment.

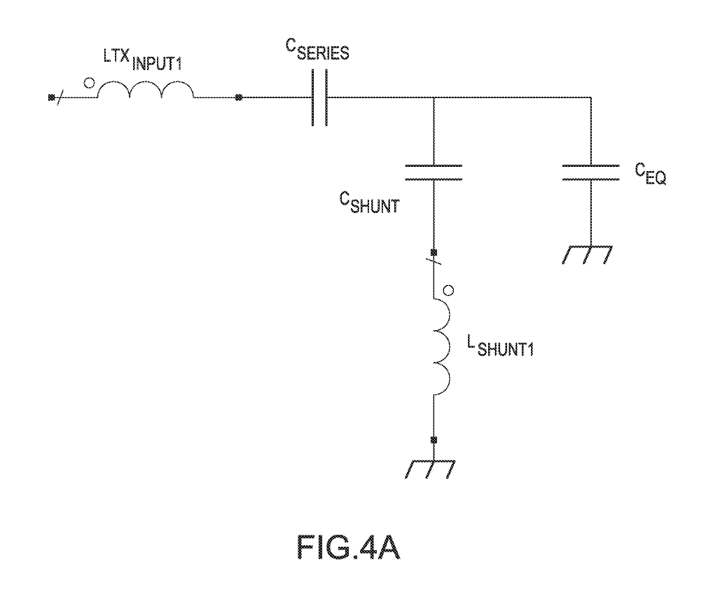

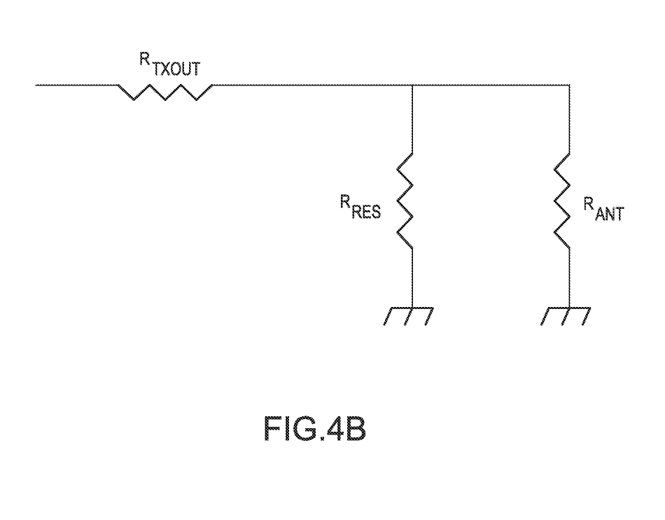

Referring to FIG. 3B, RX filter 310A comprises a ladder filter similar to that illustrated in FIG. 2. It further comprises an input inductance LTXᵢₙₚᵤₜ connected between FBARₛₑᵣᵢₑₛ₁ and FBARₛₑᵣᵢₑₛ₂, and a shunt inductance Lₛₕᵤₙₜ connected between FBARₛₕᵤₙₜ₁ and ground. Although not shown in FIG. 3B, intrinsic capacitances of the FBARs in the ladder filter of RX filter 310A operate in combination with the input inductance and shunt inductance to form a harmonic trap without the external components illustrated in FIG. 2. In other words, the harmonic trap is integrated into the ladder filter. The harmonic trap suppresses harmonic generation by TX filter 305A. An analysis of RX filter 310A is illustrated in FIGS. 4A and 4B.

One significant difference between the harmonic trap of FIG. 2 and that of FIG. 3B is that the harmonic trap of FIG. 3B does not require external capacitors, which may allow a duplexer to be manufactured with reduced size and cost. An example of a duplexer manufactured in this manner is shown in FIGS. 3C and 3D.

FIGS. 3C and 3D are a perspective view and a side view, respectively, of an FBAR duplexer module 300C comprising tuned inductors implemented by traces in a multilayer PCB substrate, according to a representative embodiment.

Referring to FIGS. 3C and 3D, duplexer module 300C comprises a module substrate 305C, two flip chip connected FBAR silicon die 315C connected to substrate 305C by solder bumps 320C, and an epoxy encapsulation layer 325C formed over the silicon die 315C. Module substrate 305C comprises a multilayer PCB (e.g., a 7 layer PCB) with integrated inductor traces 330C, 335C, and 340C, as well as vias 355C with corresponding inductances. The impedance of the integrated inductor traces can be simulated using an electromagnetic finite-element simulator, which will include parasitic capacitances and couplings not modeled in the simplified lumped element model of the circuit. In an alternative embodiment, the FBAR silicon die may also be connected to the PCB using wirebonds, and in this case the wirebond inductance may be included in the resonant trap.

The silicon die, in combination with the inductor traces and via inductances, can be used to implement a duplexer module with harmonic traps, as illustrated in FIGS. 3A and 3B. In such a module, one of silicon die 315C may implement the TX filter of FIG. 3A while the other silicon die 315C implements the RX filter of FIG. 3A. Duplexer module 300C can be mounted on a microstrip or customer PCB 310C, which includes input/output ports 345C and 350C for transmitting signals to and from a PA, LNA, or antenna port.

FIG. 4A is a simplified equivalent circuit illustrating an antenna side impedance of RX filter 310A of FIG. 3B, and FIG. 4B is a simplified equivalent circuit for the duplexer FIG. 3A at a series resonance frequency fᵣₑₛ, showing the output impedance Rtxout of the TX filter 305A, the antenna side input impedance Rres of the RX filter 310A, and the antenna impedance Rant, according to a representative embodiment.

Referring to FIG. 4A, input inductance LTXᵢₙₚᵤₜ and shunt inductance Lₛₕᵤₙₜ are the same as illustrated in FIG. 3B. Capacitances Cₛₑᵣᵢₑₛ and Cₛₕᵤₙₜ represent plate capacitances of FBARₛₑᵣᵢₑₛ₁ and FBARₛₕᵤₙₜ₁ in FIG. 3B. Capacitance C_{eq} represents the equivalent capacitance of the remaining FBAR devices in FIG. 3B.

Capacitances Cₛₑᵣᵢₑₛ and Cₛₕᵤₙₜ, in combination with input inductance LTXᵢₙₚᵤₜ and shunt inductance Lₛₕᵤₙₜ, are used to implement a harmonic trap, or LC series resonance, at the second harmonic of an adjacent filter in a multiplexer. At frequencies far removed from a piezoelectric resonance frequency of the FBAR devices, the FBAR devices are electrically equivalent to capacitors, which the capacitance approximately equal to the plate capacitance of the device.

The following analysis describes the function of RX filter 310A based on the equivalent circuits shown in FIGS. 4A and 4B. Certain parts of the analysis have been simplified in order to provide a clear explanation. For instance, capacitance C_{eq} has been ignored.

The input impedance of the RX filter has a series resonance at frequency fᵣₑₛ described by the following equation (1).

$${f}_{res} = \frac{1}{2 π} \sqrt{\frac{1}{{LTX}_{input} + {L}_{shunt}} \frac{{C}_{series} + {C}_{shunt}}{{C}_{series} {C}_{shunt}}} \qquad ( 1 )$$

At the series resonance frequency fᵣₑₛ, assuming that the losses of the resonant circuit are dominated by the equivalent series resistances Rtx and Rshunt of inductors LTXᵢₙₚᵤₜ and Lₛₕᵤₙₜ, the input impedance of the filter at fᵣₑₛ is described by the following equation (2).

Rᵣₑₛ=Rₜₓ+Rₛₕᵤₙₜ (2)

For the purpose of simplifying the analysis of the harmonic trap circuit, it is assumed that the output impedance of the TX filter at frequency fᵣₑₛ is a real impedance Rₒᵤₜ, and that the antenna port impedance at frequency fᵣₑₛ is a real impedance Rₐₙₜ. The simplified circuit is shown in FIG. 4B.

In the absence of the harmonic trap, the power at the antenna port depends on the ratio of the filter output impedance Rtxout to the antenna impedance Rant, assuming the RX filter with no harmonic trap is an effective open circuit at frequency fᵣₑₛ, as indicated approximately by the following equation (3).

$$Harmonic Power ∼ \frac{1}{{R}_{ant}} {( \frac{{R}_{ant}}{{R}_{ant} + {R}_{txout}} )}^{2} \qquad ( 3 )$$

On the other hand, with the harmonic trap circuit, most of the harmonic power is shorted to ground, and the harmonic power at the antenna port is described by the following equation (4).

$$Harmonic Power ∼ \frac{1}{{R}_{ant}} {( \frac{{R}_{ant} \vert \vert {R}_{res}}{{R}_{ant} \vert \vert {R}_{res} + {R}_{txout}} )}^{2} \qquad ( 4 )$$

The parallel resistance of the series resonance and the antenna impedance is described by the following equation (5).

$${R}_{ant} \vert \vert {R}_{res} = \frac{{R}_{ant} {R}_{res}}{{R}_{ant} + {R}_{res}} \qquad ( 5 )$$

Assuming the series resistance of the harmonic trap Rres is much less than the antenna impedance Rant, the harmonic power is described by the following equation (6).

$$Harmonic Power ∼ \frac{1}{{R}_{ant}} {( \frac{{R}_{res}}{{R}_{res} + {R}_{out}} )}^{2} \qquad ( 6 )$$

For example, assuming that at the second harmonic frequency, the equivalent series resistance of the harmonic trap is 3 Ohms, the antenna impedance is 50 Ohms, and the TX filter output impedance is 15 Ohms. Then by implementing the harmonic trap, the second harmonic power at the antenna is reduced by approximately 13 dB.

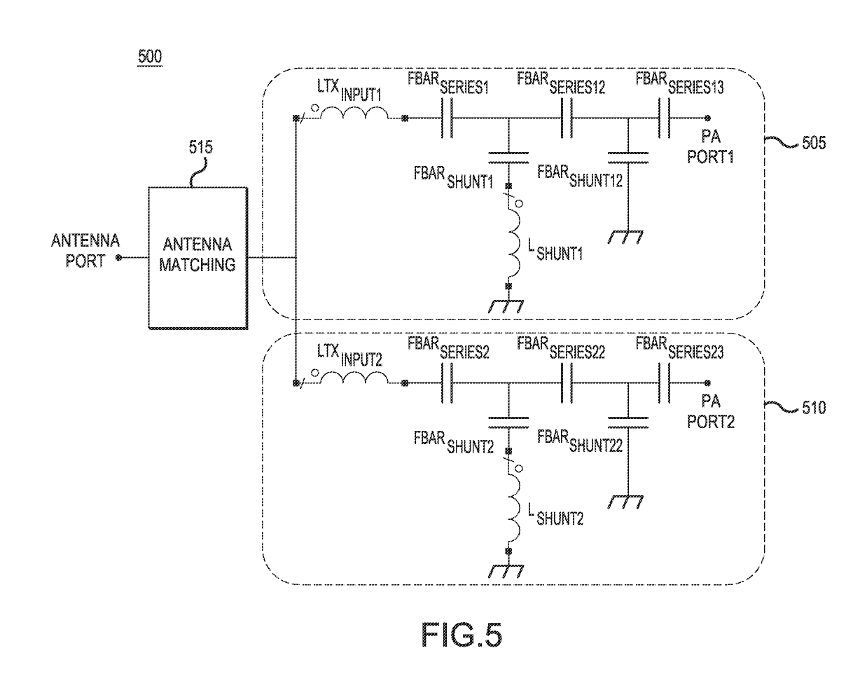

FIG. 5 is a circuit diagram illustrating a diplexer 500 comprising an integrated double harmonic trap for suppression of 2^{nd} harmonic generation, according to a representative embodiment. As will be apparent to those skilled in the art, the operating principles of diplexer 500 can be adapted for suppression of 3^{rd} harmonic suppression or higher order harmonic suppression.

Referring to FIG. 5, diplexer 500 comprises a first filter 505, a second filter 510, and an antenna matching network 515. The antenna matching network 515 may, for example, be a shunt inductor to ground. First filter 505 is connected between a first PA port (“PA Port 1”) and antenna matching network 515, and second filter 510 is connected between a second PA port (“PA Port 2”) and antenna matching network 515. For explanation purposes, it will be assumed that first and second filters 505 and 510 operate as transmit filters, although they could additionally or alternatively operate as receive filters. For example a time division duplexing (TDD) system may use the same filter in both transmit and receive modes, e.g. in a diplexer for two TDD bands, with each filter operating during some time slots as a TX filter, and during other time slots as an RX filter.

Each of first and second filters 505 and 510 has substantially the same structure as RX filter 310A of FIG. 3B, except that the harmonic trap of each of these filters is tuned according to an operating frequency (e.g., a center frequency of a passband) of the other filter. For example, the harmonic trap at the input of first filter 505 may be tuned to twice the operating frequency of second filter 510, and the harmonic trap at the input of second filter 510 may be tuned to twice the operating frequency of first filter 505.

During typical operation, both first filter 505 and second filter 510 may be used to transmit RF power to the antenna, and second harmonic generation of each transmit filter is suppressed by the harmonic trap implemented at the antenna side of the adjacent filter. The inclusion of the harmonic trap in each filter will typically have little or no impact on the size of a module including the diplexer. The tuned inductors Lₛₑᵣᵢₑₛ and Lₛₕᵤₙₜ in first and second filters 505 and 510 can be implemented as integrated components on a PCB board of the module, similar to the implementation of module 300C shown in FIGS. 3C and 3D.

In an illustrative example, suppose first filter 505 has an operating frequency of f₁ and a second harmonic at 2f₁. The harmonic trap of second filter 510 may then be tuned to have low impedance at 2f₁ to remove the second harmonic of first filter 505. Similarly, suppose second filter 510 has an operating frequency of f₂ and a second harmonic at 2f₂. The harmonic trap of first filter 505 may then be tuned to have low impedance at 2f₂ to remove the second harmonic of second filter 510.

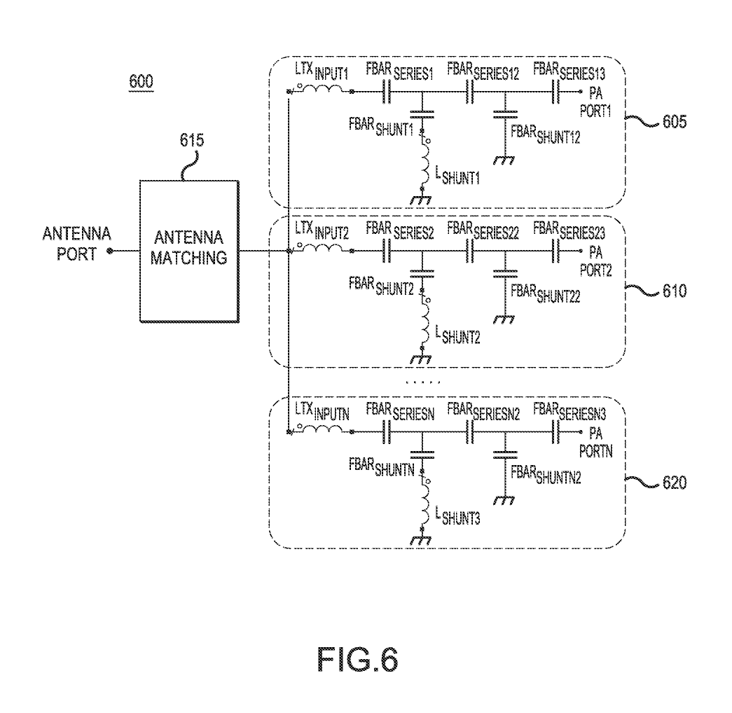

FIG. 6 is a circuit diagram illustrating a multiplexer 600 comprising multiple integrated harmonic traps for suppression of 2^{nd} harmonic generation in a multiplexer, according to a representative embodiment. As will be apparent to those skilled in the art, the operating principles of multiplexer 600 can be adapted for suppression of 3^{rd} harmonic suppression or higher order harmonic suppression.

Referring to FIG. 6, multiplexer 600 comprises N filters, including a first filter 605, a second filter 610, an N-th filter 620. It further comprises an antenna matching network 615. In this context, the number of filters N can be any number greater than 2.

First filter 605 is a TX filter connected between a first PA port (“PA Port 1”) and antenna matching network 615, second filter 610 is a TX filter connected between a second PA port (“PA Port 2”) and antenna matching network 615, and N-th filter 620 is a TX filter connected between an N-th PA port (“PA Port N”) and antenna matching network 615. For explanation purposes, it will be assumed that the first through N-th filters operate as transmit filters, although they could additionally or alternatively operate as receive filters. For example in a typical multiplexer, a single filter may be used to filter both transmitted and received signals over a particular frequency band.

The filters in multiplexer 600 may be similar to those of diplexer 500. In addition, the operation of multiplexer 600 may be similar to that of diplexer 500, except that the harmonic trap in each filter may be tuned according to an operating frequency of any of the other filters, not necessarily the one directly adjacent. For instance, in a quadplexer (i.e., N=4), the harmonic trap of first filter 605 could be tuned according to an operating frequency of a third or fourth filter, and vice versa.

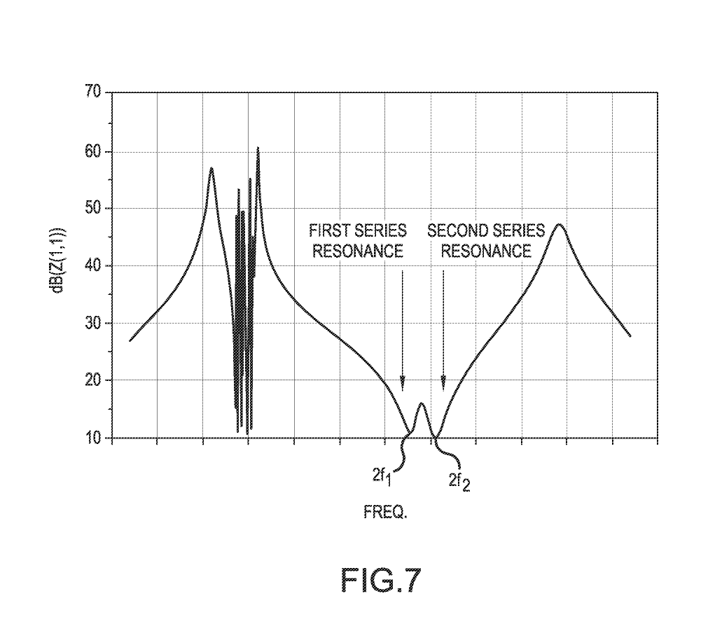

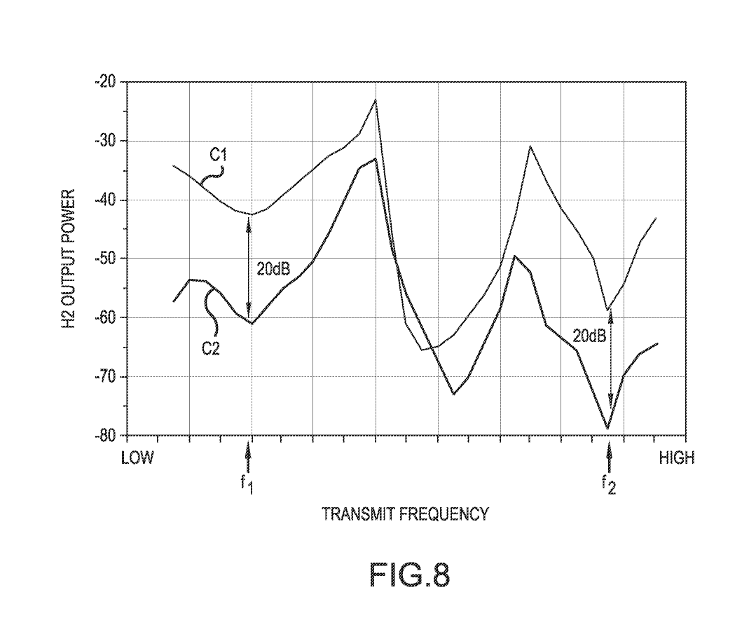

FIG. 7 is a graph illustrating diplexer antenna side output impedance, including low impedance resulting from a double harmonic trap, according to a representative embodiment, and FIG. 8 is a graph illustrating simulated 2^{nd} harmonic power output from a diplexer with and without an integrated double harmonic trap, according to a representative embodiment.

The data shown in FIGS. 7 and 8 was generated by simulation of diplexer 500, with first filter 505 having an operating frequency f₁ and a harmonic trap tuned to a frequency 2f₂, and second filter 510 having an operating frequency f₂ and a harmonic trap tuned to a frequency 2f₁. Simulated measurements of impedance and 2^{nd} harmonic power were taken at the antenna port shared by the two filters.

Referring to FIG. 7, the output impedance at the antenna port has local minima near second harmonics of the respective operating frequencies of first and second filters 505 and 510. These local minima correspond to series resonances of the harmonic traps of first and second filters 505 and 510, respectively. The presence of these local impedance minima tends to shunt the second harmonics to ground. In practice, the integrated inductor traces in the PCB may have additional mutual couplings which are not modeled in the simplified lumped element circuit, and the first and second series resonances may merge into a single low impedance resonance in the frequency range close to 2f1 and 2f2, instead of appearing as two distinct series resonances.

Referring to FIG. 8, a first curve C1 represents the 2^{nd} harmonic output power of diplexer 500 without the harmonic traps in first and second filters 505 and 510, and a second curve C2 represents the 2^{nd} harmonic output power of diplexer 500 with the harmonic traps in first and second filters 505 and 510. At the respective operating frequencies of first and second filters 505 and 510, the harmonic traps reduce the 2^{nd} harmonic output power by about 20 dB.

While example embodiments are disclosed herein, one of ordinary skill in the art appreciates that many variations that are in accordance with the present teachings are possible and remain within the scope of the appended claims. The embodiments therefore are not to be restricted except within the scope of the appended claims.

1. A multiplexer, comprising:
a plurality of acoustic resonator based filters having different operating frequencies and connected to a common node; and
a plurality of harmonic traps each integrated with a corresponding one of the filters and tuned to suppress at least one harmonic generated by another one of the filters.

2. The multiplexer of claim 1, wherein the common node is an antenna port of a wireless communication device.

3. The multiplexer of claim 2, wherein at least one of the filters comprises a transmit filter configured to filter signals transmitted from a power amplifier to the antenna port, and at least one of the filters comprises a receive filter configured to filter signals transmitted from the antenna port to a low noise amplifier.

4. The multiplexer of claim 2, wherein at least one of the filters is configured to operate both as a transmit filter to filter signals transmitted from a power amplifier to the antenna port, and as a receive filter to filter signals transmitted from the antenna port to a low noise amplifier.

5. The multiplexer of claim 1, wherein at least one of the acoustic resonator based filters comprises a plurality of series connected film bulk acoustic resonators (FBARs) and a plurality of shunt connected FBARs arranged in a ladder filter.

6. The multiplexer of claim 5, wherein a harmonic trap integrated with the ladder filter has a tuning defined by an intrinsic capacitance of at least one of the series connected FBARs, an intrinsic capacitance of at least one of the shunt connected FBARs, and an inductance integrated into a printed circuit board (PCB).

7. The multiplexer of claim 1, wherein each of the harmonic traps comprises a capacitance associated with at least one acoustic resonator, an input inductance of the common node, and an inductance integrated into a printed circuit board (PCB).

8. The multiplexer of claim 7, wherein the acoustic resonator filters are mounted on the printed circuit board.

9. The multiplexer of claim 8, wherein the acoustic resonator filters are disposed in a flip chip package disposed on the PCB over at least a portion of the integrated inductances.

10. The multiplexer of claim 1, wherein the plurality of acoustic resonator based filters comprises a first filter having a first operating frequency and a second filter having a second operating frequency different from the first operating frequency, and wherein a harmonic trap integrated with the first filter has a series resonance at approximately twice the second operating frequency, and a harmonic trap integrated with the second filter has a series resonance at approximately twice the first operating frequency.

11. The multiplexer of claim 10, wherein the first and second filters constitute a duplexer, wherein the first filter is a receive filter of the duplexer and the second filter is a transmit filter of the duplexer.

12. The multiplexer of claim 1, wherein the plurality of acoustic resonator based filters comprises at least three filters.

13. The multiplexer of claim 1, wherein the at least one suppressed harmonic comprises a second order harmonic of an operating frequency of at least one of the acoustic resonator based filters.

14. The multiplexer of claim 1, wherein the at least one suppressed harmonic comprises a third or higher order harmonic of an operating frequency of at least one of the acoustic resonator based filters.

15. An apparatus, comprising:
a module substrate; and
a filter module disposed on the module substrate and comprising a plurality of acoustic resonator based filters having different operating frequencies and connected to a common node, and a plurality of harmonic traps each integrated with a corresponding one of the filters and tuned to suppress at least one harmonic generated by another one of the filters.

16. The apparatus of claim 15, wherein the module substrate comprises a printed circuit board (PCB), and at least one of the harmonic traps comprises an inductance integrated into the PCB and an intrinsic capacitance of at least one acoustic resonator of a corresponding one of the filters.

17. The apparatus of claim 15, further comprising:
an antenna port connected to the common node;
an antenna switch configured to selectively connect the antenna port to the plurality of acoustic resonator based filters;
an amplifier; and
a radio frequency switch configured to selectively connect the amplifier to one of the filters.

18. A multiplexer, comprising:
a plurality of filters connected to a common node and each comprising a plurality of acoustic resonators; and
a plurality of harmonic traps each integrated into a corresponding one of the plurality of filters and configured to suppress harmonic generation of another one of the filters.

19. The multiplexer of claim 18, wherein at least one of the filters comprises a plurality of series connected acoustic resonators and a plurality of shunt acoustic resonators connected in parallel with the series connected acoustic resonators, and wherein at least one of the integrated harmonic traps comprises a first inductor disposed in series with the series connected acoustic resonators and a second inductor disposed between one of the shunt acoustic resonators and ground.

20. The multiplexer of claim 18, wherein the multiplexer is a diplexer, and the plurality of filters comprise first and second filters having integrated first and second harmonic traps, respectively.

21. The multiplexer of claim 20, wherein the first harmonic trap is tuned to approximately twice an operating frequency of the second filter, and the second harmonic trap is tuned to approximately twice an operating frequency of the second filter.
